(19) United States
(12) Patent Application Publication
(10) Pub. No.: US 2024/0404968 A1
(43) Pub. Date: Dec. 5, 2024

(54) Semiconductor Packaging Method

(71) Applicant: SHENZHEN SIPTORY TECHNOLOGY CO., LTD, Shenzhen (CN)

(72) Inventor: Dongdong Shao, Shenzhen (CN)

(21) Appl. No.: 18/798,762

(22) Filed: Aug. 8, 2024

Related U.S. Application Data
(63) Continuation of application No. PCT/CN2023/075418, filed on Feb. 10, 2023.

(30) Foreign Application Priority Data
Feb. 11, 2022 (CN) 202210126914.7

(51) Int. Cl. H01L 23/00; H01L 23/31; H01L 23/495

(52) U.S. Cl. CPC H01L 24/03; H01L 24/05; H01L 24/19; H01L 24/24; H01L 23/3107; H01L 23/495; H01L 2224/0384; H01L 2224/05557; H01L 2224/19; H01L 2224/24246

(57) ABSTRACT

The present invention relates to a semiconductor packaging method, comprising mounting a chip on a lead frame, and producing a wire end structure on an AL bonding pad on the upper surface of the chip using a lead bonding process; realizing modification of the AL bonding pad toward gold balls or copper balls to carry out subsequent packaging processes. The method can avoid the limitation of the wire bonding process on enhancing relevant performances of the product, and can avoid the complex and high-cost bonding pad modification or RDL process. The present invention further provides a packaging structure and packaging product obtained using the above method.

### CROSS REFERENCE TO RELATED APPLICATIONS

The present application is a Continuation Application of PCT Application No. PCT/CN2023/075418 filed on Feb. 10, 2023, which claims the benefit of Chinese Patent Application No. 202210126914.7 filed on Feb. 11, 2022. All the above are hereby incorporated by reference in their entirety.

### TECHNICAL FIELD

This invention relates to the field of semiconductor packaging technology, specifically to a semiconductor packaging method and packaging structure.

### BACKGROUND ART

As a traditional semiconductor packaging process, the wire bonding process has been widely used in the packaging of chips in various fields (FIG. 1, traditional wire bonding product packaging structure), including lead frame 1, chip 2, lead wire 7, and packaging layer 4. However, with the increasingly extreme demands for product performance: such as internal resistance of the product requiring the internal parasitic resistance of package to be as low as possible, and the heat dissipation of the product requiring the packaging body to have increasingly strong heat dissipation abilities, etc., the wire diameter processed by the wire bonding process (lead bonding) is generally small (the diameter of lead 7, generally at 20-30 μm), which has become a bottleneck for further improvement of product performance. Currently, new advanced packaging processes utilize traditional PCBs (Printed Circuit Boards) or substrates (with the packaging substrate referred to as substrate, abbreviated as SUB). Substrates can provide electrical connection, protection, support, heat dissipation, and assembly functions for chips, so as to achieve multi-pinching, reduce the volume of packaging products, improve electrical performance and heat dissipation, and achieve ultra-high density or multi-chip modularization. Industry blind hole interconnection technology (FIG. 2, a schematic diagram of chip packaging through blind hole interconnection) uses blind holes filled with conducting materials in replacement of traditional wire bonding processes. This includes packaging substrate 8, chip 2, chip blind hole 51, internal connection line 9, and packaging layer 4. Both the internal resistance of the product and the heat dissipation performance of the packaging body are improved to a certain extent.

### Technical Problems

Regarding a chip welding pad junction in traditional wire bonding processes (as shown in FIG. 3, chip welding pad junction-chip bonding pad), the surface material of the bottom bonding pad of the welding pad junction is aluminum (FIG. 4). Eutectic bonding is realized through aluminum metal and gold wire (according to the principle of eutectic bonding, eutectic bonding is also called low-melting-point alloy welding). The basic characteristic of eutectic alloy is that two different metals can form an alloy according to a certain weight ratio at a temperature much lower than their individual melting points. The most commonly used eutectic bonding in microelectronic devices is to bond chips to a gold-plated base or lead frame, i.e. “gold-core eutectic bonding”.

However, aluminum is an active metal, and its resistance to acids and bases is poor. At the present stage, the blind hole interconnection technology (FIG. 2) requires the use of the electroplating process in the PCB or substrate industry. At this point, the aluminum bonding pad can no longer meet the requirements, and it is necessary to modify the chip welding pad or perform RDL (Redistribution Layer, which is a process of changing the junction of the original IC circuit junction (I/O pad) through wafer-level metal wiring process and bumping process, so that the IC can be adapted to different packaging forms) operations (as shown in FIG. 5, modifying the AL bonding pad to a Cu bonding pad). The most common method is to add a copper redistribution layer to match the blind hole interconnection technology.

For one thing, the wire bonding process has limitations on enhancing relevant performances of the product, and for another, the new blind hole interconnection process requires additional complex and high-cost bonding pad modification or RDL for existing conventional chips. How to effectively solve the above problems is worth researching.

### Technical Solutions

In light of the above, the present invention provides a semiconductor packaging method, which, for one thing, can avoid the limitation of the wire bonding process on enhancing relevant performances of the product, and for another, can avoid the complex and high-cost bonding pad modification or RDL process.

A semiconductor packaging method, which includes:

Step A. Mounting a chip on a lead frame, and producing a wire end structure on an AL bonding pad on the upper surface of the chip using a lead bonding process; the wire end structure including a wire bonding pad contact ball, a transition connection platform, and a wire end, which are tightly connected from bottom to top;

Step B. Subjecting the lead frame whose wire end structure has been produced to first plastic packaging or compression encapsulation to realize full packaging of the chip and the wire end structure, with the top surface of the packaging layer being 20 to 50 μm higher than the top surface of the wire end structure;

Step C. Thinning the packaging layer until the wire bonding pad contact ball is exposed, removing the transitional connecting platform and the wire end.

Preferably, the conducting wire used in the lead bonding process is a gold or copper wire, wherein the diameter of the conducting wire is defined as d and the diameter of the wire bonding pad contact ball as D, with D≥3d.

Preferably, the conducting wire used in the lead bonding process is a variable-diameter wire, which includes more than N interconnected ball units. Each ball unit includes a wire end part, a variable-diameter part, and a joint part. The diameters of the wire end part and joint part are equal to the diameter of the conducting wire. The variable-diameter part is larger in the middle and smaller at both ends, with the maximum diameter being 2 to 4 times the diameter of the conducting wire.

The lead bonding process involves the use of more than two bonding needles, each of which guides conducting wires for simultaneous bonding. More than two wire end structures are eutectically fused with each other to form a large wire end structure, wherein N is a natural number.

Regarding the wire end structure, the conducting wire used for lead bonding is a copper wire, with the diameter of the copper wire defined as d, and the diameter of the wire bonding pad contact ball as D. The wire bonding process (lead bonding) adjusts the pressure, vibration, or other parameters of the wire bonder to achieve D≥3d; taking the common copper wire with the diameter of 0.8 mil/20 μm (1 mil= 1/1000 inch=0.0254 mm) as an example, the diameter of the wire bonding pad contact ball can be controlled between 60 and 70 μm. The minimum size of the aluminum bonding pad of the common wire bonding chip is about 80 μm, and under normal circumstances, it basically can be fully matched and connected with the diameter of the wire bonding pad contact ball to the greatest extent.

Preferably, there is more than one AL bonding pad, each of which has more than one wire end structure. The wire bonding pad contact ball having more than one wire end structure completely covers the surface of the AL bonding pad, and adjacent wire bonding pad contact balls are eutecticly fused at the junction.

Preferably, the conducting wire used in the lead bonding process is a zinc-coated copper wire, with the thickness of the zinc layer being 10% to 60% of the thickness of the conducting wire. Zinc has a low melting point and can form an intermediate that combines aluminum and copper, so it is an excellent transition layer metal.

Preferably, when the bottom size of the chip blind hole is less than or equal to the diameter D of the wire bonding pad contact ball, the method further includes: Step D. Subjecting the thinned packaging layer to secondary plastic packaging or secondary compression encapsulation, with the thickness of the secondary packaging layer being 35 to 50 μm.

Step E. Manufacturing chip blind holes and circuit interconnecting holes on the wire bonding pad contact ball;

Step F. Subjecting the formed chip blind holes and circuit interconnecting holes to electroplating and patterned circuit processing to achieve electrical interconnection of the product.

Preferably, when the bottom size of the chip blind hole is greater than the diameter D of the wire bonding pad contact ball, the method further includes:

Step C1. Conducting metallization processing on the product surface whose wire bonding pad contact ball is exposed after thinning, which can be done using methods such as chemical plating, sputtering, or vapor deposition to create a large bonding pad that covers the wire bonding pad contact ball. The thickness of the large bonding pad is 15 to 25 μm, and the edge of the large bonding pad is more than 3 μm greater than the edge of the wire bonding pad contact ball.

Step D. Subjecting the packaging layer for making the large bonding pad to secondary plastic packaging or secondary compression encapsulation, with the thickness of the secondary packaging layer being 35 to 50 μm.

Step E. Manufacturing chip blind holes and circuit interconnecting holes on the large bonding pad; subjecting the surface metal layer to patterned circuit processing, thereby further enlarging the cross-sectional dimension of the wire bonding pad contact ball exposed after thinning; defining the bottom size (diameter) of the chip blind hole as φ, the positioning accuracy of the hole processing equipment as ±Δ, and the pattern size of the large bonding pad as T (assuming the large bonding pad is circular with a diameter of T to ensure full coverage); then subjecting the surface metal layer to patterned processing to achieve a patterned dimension parameter of T≥φ+2Δ, ensuring that the bottom of the chip blind hole is above the large bonding pad and that the large bonding pad completely covers the wire bonding pad contact ball.

Step F. Subjecting the formed chip blind hole and circuit interconnecting hole to electroplating and patterned circuit processing to achieve electrical interconnection of the product.

Preferably, in Step A, the lead frame is equipped with a thickness adjustment protrusion, the thickness of which is 95% to 105% of the total thickness of the chip and the wire bonding pad contact ball. To further reduce the processing difficulty of the large and small interconnecting holes, a 3D protrusion frame (thickness adjustment protrusion) that can reduce the size of the large interconnecting hole is designed. It significantly reduces the size of the large blind hole, greatly narrows the size difference between the interconnecting holes, and thereby greatly reduces the processing difference of the interconnecting holes.

Wire end structure 3 can also be used. The conducting wire used for lead bonding is defined as copper wire with a diameter of d, and the diameter of the wire bonding pad contact ball 31 as D. The wire bonding process (lead bonding) adjusts the pressure, vibration, or other parameters of the wire bonder to achieve D≥3d; taking the common copper wire with the diameter of 0.8 mil/20 μm (1 mil= 1/1000 inch=0.0254 mm) as an example, the diameter of the wire bonding pad contact ball 31 can be controlled between 60 and 70 μm. The minimum size of the aluminum bonding pad of the common wire bonding chip is about 80 μm, and under normal circumstances, it basically can be fully matched and connected with the diameter of the wire bonding pad contact ball to the greatest extent.

The present invention further provides a packaging structure made by the above semiconductor packaging method.

A semiconductor packaging structure includes a lead frame, a chip, and a packaging layer. The chip is fixed on the lead frame, and the packaging layer encases the chip and the lead frame. The upper surface of the chip is equipped with an AL bonding pad, and the AL bonding pad is equipped with wire bonding pad contact balls that have had the wire end and transitional connecting platform removed. The wire bonding pad contact balls are electrically connected to surface bonding pads or surface circuits on the packaging layer through chip blind holes;

A large bonding pad is set above the wire bonding pad contact ball, with the size of the large bonding pad greater than the bottom size of the chip blind hole; or there is no large bonding pad set above the wire bonding pad contact ball, with the size of the wire bonding pad contact ball greater than the bottom size of the chip blind hole.

Preferably, there is more than one AL bonding pad, each of which is equipped with more than one wire end structure. The wire bonding pad contact ball having more than one wire end structure completely covers the surface of the AL bonding pad, and adjacent wire bonding pad contact balls are eutecticly fused at the junction to form a large wire end structure.

The conducting wire used in the lead bonding process is a gold wire, copper wire or zinc-coated copper wire.

When the conducting wire used in the lead bonding process is a zinc-coated copper wire, the thickness of the zinc layer is 10% to 60% of the thickness of the conducting wire. Zinc has a low melting point and can form an intermediate that combines aluminum and copper, so it is an excellent transition layer metal.

Wire end structure 3 can also be used. The conducting wire used for lead bonding is defined as copper wire with a diameter of d, and the diameter of the wire bonding pad contact ball 31 as D. The wire bonding processing (lead bonding) adjusts the pressure, vibration, or other parameters of the wire bonder to achieve D≥3d; taking the common copper wire with the diameter of 0.8 mil/20 μm (1 mil= 1/1000 inch=0.0254 mm) as an example, the diameter of the wire bonding pad contact ball 31 can be controlled between 60 and 70 μm. The minimum size of the aluminum bonding pad of the common wire bonding chip is about 80 μm, and under normal circumstances, it basically can be fully matched and connected with the diameter of the wire bonding pad contact ball to the greatest extent.

The beneficial effects of the present invention are: a semiconductor packaging method, including: mounting chips on a lead frame, and producing a wire end structure on the AL bonding pad on the upper surface of the chip using the lead bonding process; the wire end structure including a wire bonding pad contact ball, a transition connection platform, and a wire end, which are tightly connected from bottom to top; performing first plastic packaging or compression encapsulation to realize full packaging of the chip and the wire end structure, with the top surface of the packaging layer being 20 to 50 μm higher than the top surface of the wire end structure; thinning the packaging layer until the wire bonding pad contact ball is exposed, removing the transitional connecting platform and the wire end, thereby realizing modification of the AL bonding pad toward gold balls or copper balls to carry out subsequent packaging processes. The method for one thing can avoid the limitation of the wire bonding process on enhancing relevant performances of the product, and for another, can avoid the complex and high-cost bonding pad modification or RDL process. The present invention further provides a packaging structure and packaging product obtained using the above method.

### DESCRIPTION OF DRAWINGS

FIG. 1 is a schematic diagram of the packaging structure of a traditional wire bonding (lead packaging process) product.

FIG. 2 is a schematic diagram of the product for chip packaging through blind hole interconnection.

FIG. 3 is a schematic diagram of the chip and chip welding pad junction during traditional wire bonding process.

FIG. 4 is a schematic diagram of the chip welding pad junction (chip bonding pad, AL bonding pad) of FIG. 3.

FIG. 5 is a schematic diagram where the AL bonding pad is modified to a Cu bonding pad after the chip welding pad has undergone modification or RDL.

FIG. 6 is a schematic diagram after a wire end structure has been created on the chip AL bonding pad using the lead bonding process following mounting of chips on a lead frame using the semiconductor packaging method of the present invention.

FIG. 7 is a schematic diagram of the wire end structure in FIG. 6.

FIG. 8 is a schematic diagram of a combination of the lead frame, chip, chip bonding pad, wire bonding pad contact ball, and chip blind hole in the semiconductor packaging structure of the present invention.

FIG. 9 is a schematic diagram of an example of the semiconductor packaging structure of the present invention, where the bottom size of the chip blind hole is less than or equal to the diameter D of the wire bonding pad contact ball.

FIG. 10 is a detailed local structure view of area A in FIG. 9.

FIG. 11 is a schematic diagram of an example of the semiconductor packaging structure of the present invention, where the bottom size of the chip blind hole is greater than the diameter D of the wire bonding pad contact ball.

FIG. 12 is a detailed local structure view of area B in FIG. 11.

FIG. 13a is a schematic diagram after mounting of chips on a lead frame in Example 1 of the semiconductor packaging method of the present invention.

FIG. 13b is a schematic diagram after mounting of packaging layer 4 on a lead frame in Example 1 of the semiconductor packaging method of the present invention.

FIG. 13c is a schematic diagram of thinning to expose the wire bonding pad contact ball 31 in Example 1 of the semiconductor packaging method of the present invention.

FIG. 13d is a schematic diagram of secondary plastic packaging or secondary compression encapsulation in Example 2 of the semiconductor packaging method of the present invention.

FIG. 13e is a schematic diagram after manufacture of chip blind hole 51 and circuit interconnecting hole 52 in Example 2 of the semiconductor packaging method of the present invention.

FIG. 13f is a schematic diagram after manufacture of patterned circuit processing in Example 2 of the semiconductor packaging method of the present invention.

FIG. 13g is a schematic diagram after tertiary plastic packaging in Example 2 of the semiconductor packaging method of the present invention.

FIG. 14 is a schematic diagram of the variable-diameter conducting wire (variable-diameter lead) in Example 3 of the semiconductor packaging method of the present invention.

FIG. 15 is a schematic diagram of the wire end structure 30 in Example 4 of the semiconductor packaging method of the present invention.

FIG. 16a is a schematic diagram after manufacture of metal layer 02 in Example 6 of the semiconductor packaging method of the present invention.

FIG. 16b is a schematic diagram after manufacture of large bonding pad 311 in Example 6 of the semiconductor packaging method of the present invention.

FIG. 16c is a schematic diagram after manufacture of secondary packaging layer 5 in Example 6 of the semiconductor packaging method of the present invention.

FIG. 16d is a schematic diagram after manufacture of chip blind hole 51 and circuit interconnecting hole 52 in Example 6 of the semiconductor packaging method of the present invention.

FIG. 16e is a schematic diagram after manufacture of patterned circuit processing in Example 6 of the semiconductor packaging method of the present invention.

FIG. 16f is a schematic diagram after tertiary plastic packaging in Example 6 of the semiconductor packaging method of the present invention.

FIG. 17a is a schematic diagram of thickness adjustment protrusion 11 in step A of Example 7 of the semiconductor packaging method of the present invention.

FIG. 17b is a schematic diagram of an example of the semiconductor packaging structure of the present invention, providing a thickness adjustment protrusion 11, and not providing a large bonding pad when the bottom size of the chip blind hole is less than or equal to the diameter D of the wire bonding pad contact ball.

FIG. 17c is a schematic diagram of an example of the semiconductor packaging structure of the present invention, providing a thickness adjustment protrusion 11, and providing a large bonding pad when the bottom size of the chip blind hole is less than or equal to the diameter D of the wire bonding pad contact ball.

### IN THE FIGURES

1—lead frame; 11—thickness adjustment protrusion; 2—chip; 21—AL bonding pad; 3—wire end structure; 30—large wire end structure; 31—wire bonding pad contact ball; 311—large bonding pad; 32—transition connection platform; 33—wire end; 4—packaging layer; 5—secondary packaging layer; 51—chip blind hole; 52—circuit interconnecting hole; 6—ball unit; 61—wire end part; 62—variable-diameter part; 63—joint part; 7—lead; 8—packaging substrate; 9—internal connection line; 01—tertiary packaging layer; 02—metal layer.

### BEST MODES FOR CARRYING OUT THE INVENTION

A semiconductor packaging method, which includes:

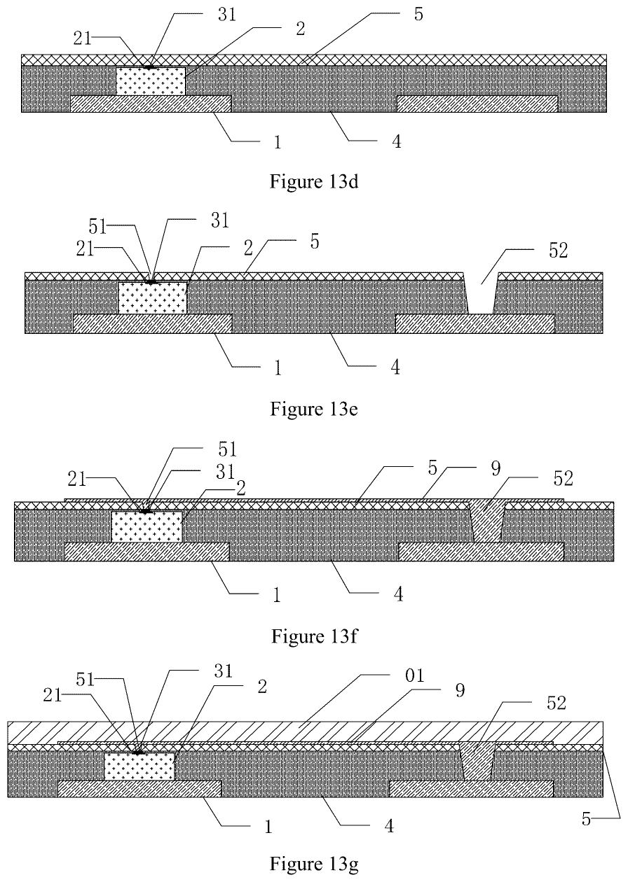

Step A. Mounting a chip 2 on a lead frame 1, and producing a wire end structure 3 on an AL bonding pad 21 on the upper surface of the chip 2 using a lead bonding process; the wire end structure 3 including a wire bonding pad contact ball 31, a transitional connecting platform 32, and a wire end 33, which are tightly connected from bottom to top; as shown by combining FIGS. 13a and 7;

Step B. Subjecting the lead frame 1 whose wire end structure 3 has been produced to first plastic packaging or compression encapsulation to realize full packaging of the chip 2 and the wire end structure 3, with the top surface of the packaging layer 4 being 20 to 50 μm higher than the top surface of the wire end structure 3; as shown by combining FIG. 13b;

Step C. Thinning the packaging layer 4 until the wire bonding pad contact ball 31 is exposed, removing the transitional connecting platform 32 and the wire end 33. The residual height of the wire bonding pad contact ball 31 after thinning is defined as H, the head diameter of the wire bonding pad contacting ball 31 after thinning as R, and the bottom diameter of the wire bonding pad contacting ball 31 after thinning as D, to match the thinning height reserved in Step B, wherein d is the diameter of the lead for lead bonding, which meets the following process parameter requirements: 2d≤R<3d and 10 μm≤H<30 μm; as shown by combining FIGS. 7 and 13c.

In the examples, the conducting wire used in the lead bonding process is a gold or copper wire, wherein the diameter of the conducting wire is defined as d and the diameter of the wire bonding pad contact ball 31 as D, with D≥3d.

### EMBODIMENTS OF THE PRESENT INVENTION

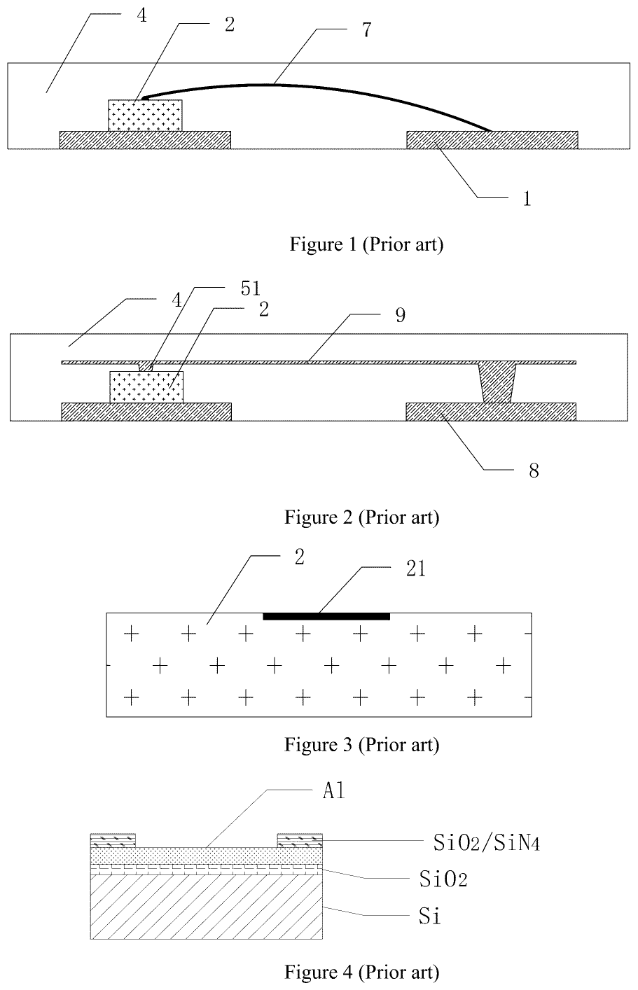

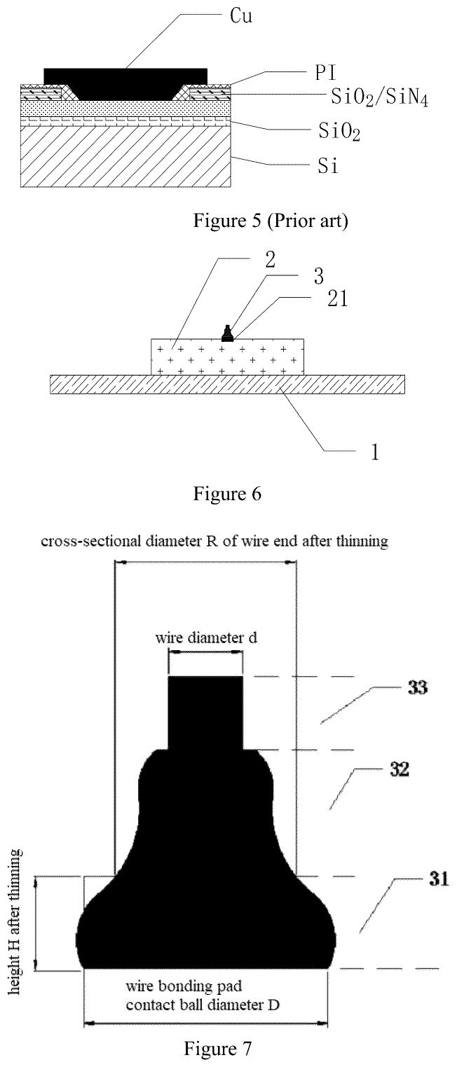

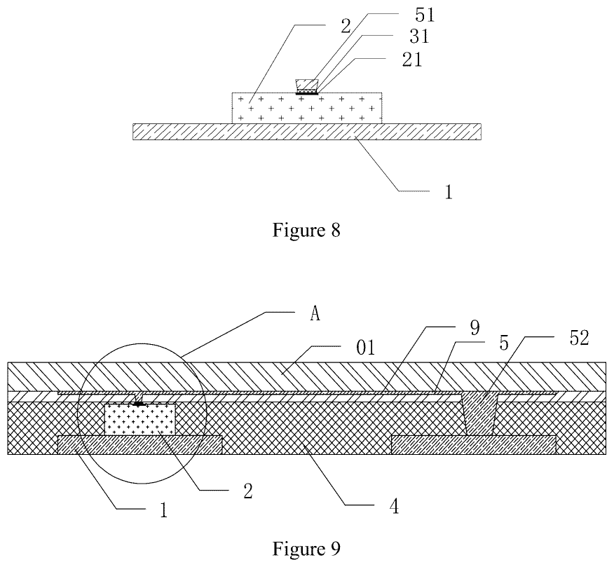

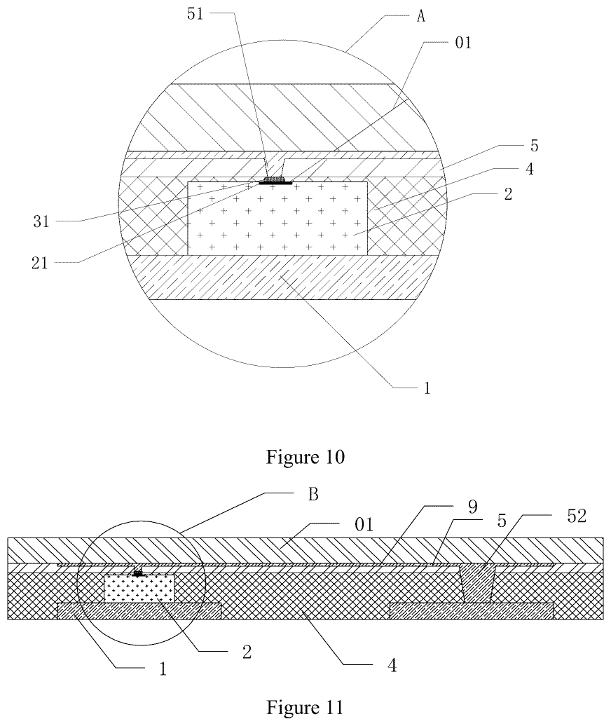

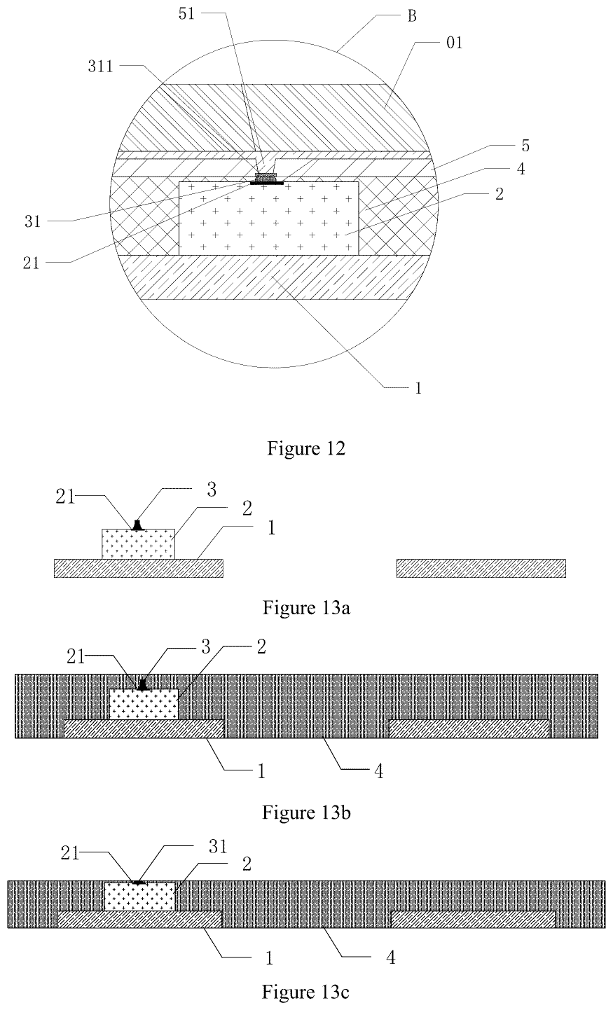

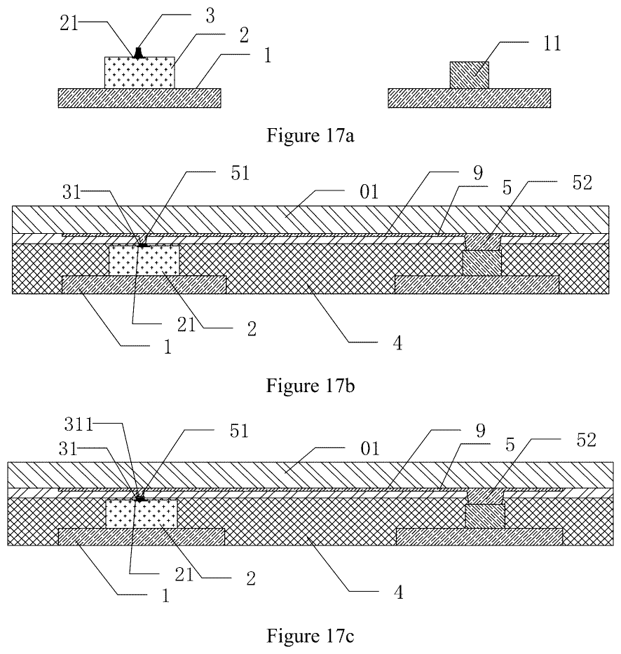

Technical solutions of a semiconductor packaging method and packaging structure are further illustrated below through embodiments in combination with FIGS. 1-17c.

### Example 1

A semiconductor packaging method, which includes:

Step A. Mounting a chip 2 on a lead frame 1, and producing a wire end structure 3 on an AL bonding pad 21 on the upper surface of the chip 2 using a lead bonding process; the wire end structure 3 including a wire bonding pad contact ball 31, a transitional connecting platform 32, and a wire end 33, which are tightly connected from bottom to top; as shown by combining FIGS. 13a and 7;

Step B. Subjecting the lead frame 1 whose wire end structure 3 has been produced to first plastic packaging or compression encapsulation to realize full packaging of the chip 2 and the wire end structure 3, with the top surface of the packaging layer 4 being 20 to 50 μm higher than the top surface of the wire end structure 3; as shown by combining FIG. 13b;

Step C. Thinning the packaging layer 4 until the wire bonding pad contact ball 31 is exposed, removing the transitional connecting platform 32 and the wire end 33. The residual height of the wire bonding pad contact ball 31 after thinning is defined as H, the head diameter of the wire bonding pad contacting ball 31 after thinning as R, and the bottom diameter of the wire bonding pad contacting ball 31 after thinning as D, to match the thinning height reserved in Step B, wherein d is the diameter of the lead for lead bonding, which meets the following process parameter requirements: 2d≤R<3d and 10 μm≤H<30 μm; as shown by combining FIGS. 7 and 13c.

FIGS. 13d-13g are combined.

The example further comprises:

Step D. Subjecting the thinned packaging layer 4 to secondary plastic packaging or secondary compression encapsulation, with the thickness of the secondary packaging layer 5 being 35 to 50 μm.

Step E. Manufacturing chip blind holes 51 and circuit interconnecting holes 52 on the wire bonding pad contact ball 31;

Step F. Subjecting the formed chip blind holes 51 and circuit interconnecting holes 52 to electroplating and patterned circuit processing to achieve electrical interconnection of the product, wherein internal connection line 9 connects the chip blind hole 51 and the circuit interconnecting hole 52.

In the example, the bottom size of the chip blind hole 51 is less than or equal to the diameter D of the wire bonding pad contact ball 31.

In the example, if it is not wished to expose the top circuit, further plastic packaging of the top can be conducted to make tertiary packaging layer 01 and realize full coverage protection of the product circuit.

### Example 2

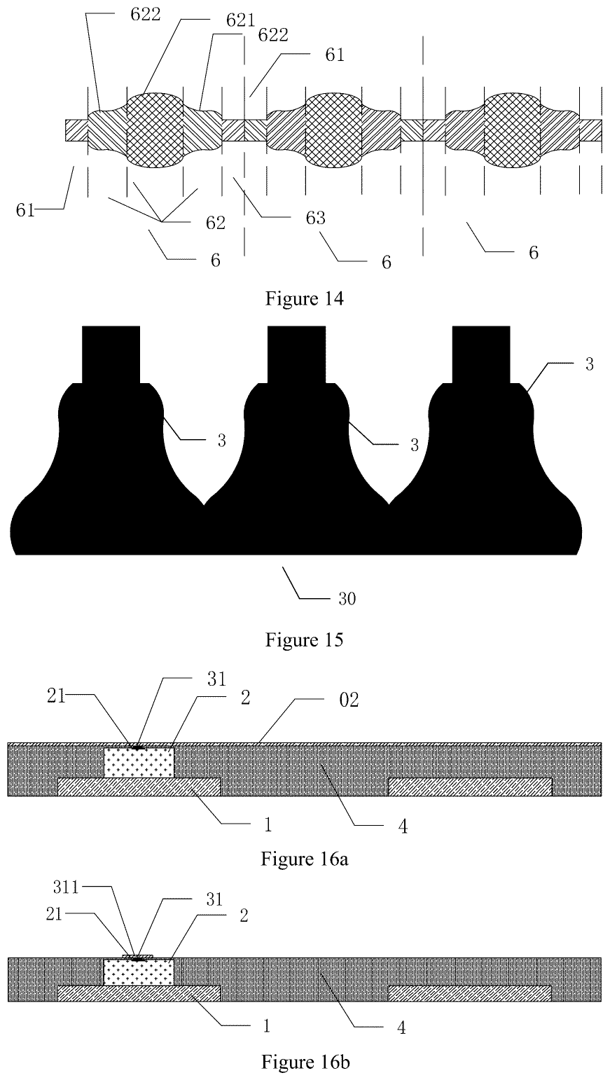

In the example, the conducting wire used in the lead bonding process is a variable-diameter wire, which includes more than N interconnected ball units 6. Each ball unit includes a wire end part 61, a variable-diameter part 62, and a joint part 63. The diameters of the wire end part 61 and joint part 63 are equal to the diameter of the conducting wire. The variable-diameter part 62 is larger in the middle and smaller at both ends, with the maximum diameter being 2 to 4 times the diameter of the conducting wire, as shown in FIG. 14.

N is a natural number greater than or equal to 10.

The variable-diameter part 62 includes central main ball 621 and transitional connecting balls 622 on two sides. In manufacture of the wire end structure 3, the central main ball 621 becomes the main body of the wire bonding pad contact ball 31, and the transitional connecting balls 622 are respectively fused on both sides of the main body of the wire bonding pad contact ball 31, also called part of the wire bonding pad contact ball 31. Parts of the wire end part 61 and the joint part 63 are truncated and discarded, while parts are melted into the transitional connecting platform 32. By providing a variable-diameter conducting line, the volume and radius of the wire bonding pad contact ball 31 can be increased, achieving full coverage of the chip AL bonding pad.

In the example, the unspecified portions can be the same as Example 1 or Example 2.

### Example 3

The lead bonding process involves the use of more than two bonding needles, each of which guides conducting wires for simultaneous bonding. More than two wire end structures 3 are eutectically fused with each other to form a large wire end structure 30, as shown in FIG. 15.

### Example 4

Different from Example 3, one bonding needle is used.

There is more than one AL bonding pad 21, each of which is equipped with more than one wire end structure 3. The wire bonding pad contact ball 31 having more than one wire end structure 3 completely covers the surface of the AL bonding pad 21, and adjacent wire bonding pad contact balls 31 are eutecticly fused at the junction, as shown in FIG. 15. This example achieves full coverage of the chip bonding pad, 100% coverage, which not only ensures complete coverage but also avoids any exposure at the edges.

In the example, the conducting wire used in the lead bonding process is a zinc-coated copper wire, with the thickness of the zinc layer being 10% to 60% of the thickness of the conducting wire. Zinc has a low melting point and can form an intermediate that combines aluminum and copper, so it is an excellent transition layer metal.

### Example 5

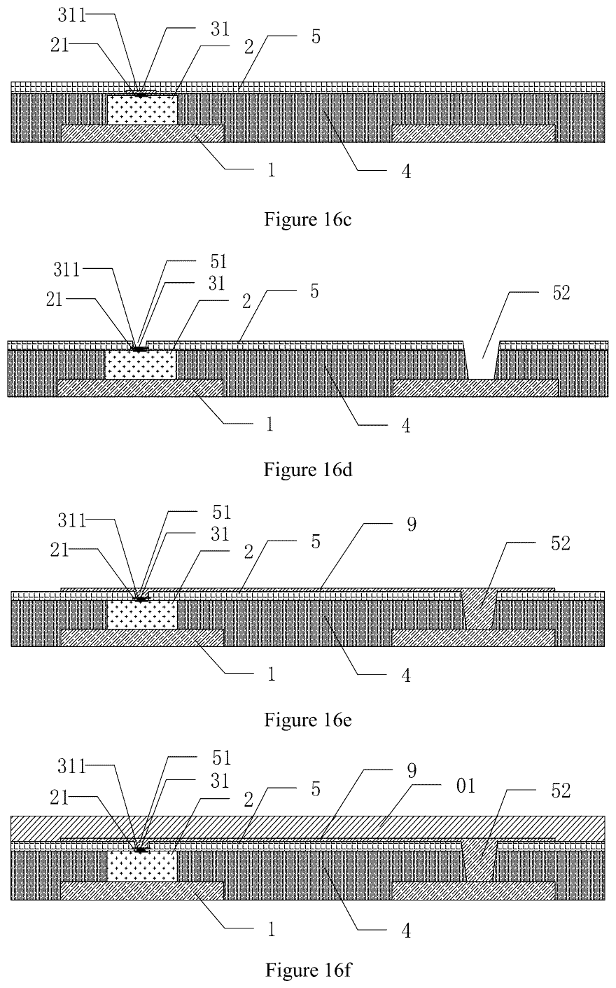

FIGS. 13a, 13b, 13c and 16a are combined.

A semiconductor packaging method, which includes:

Step A. Mounting a chip 2 on a lead frame 1, and producing a wire end structure 3 on an AL bonding pad 21 on the upper surface of the chip 2 using a lead bonding process; the wire end structure 3 including a wire bonding pad contact ball 31, a transitional connecting platform 32, and a wire end 33, which are tightly connected from bottom to top; as shown by combining FIGS. 13a and 7;

Step B. Subjecting the lead frame 1 whose wire end structure 3 has been produced to first plastic packaging or compression encapsulation to realize full packaging of the chip 2 and the wire end structure 3, with the top surface of the packaging layer 4 being 20 to 50 μm higher than the top surface of the wire end structure 3; as shown by combining FIG. 13b;

Step C. Thinning the packaging layer 4 until the wire bonding pad contact ball 31 is exposed, removing the transitional connecting platform 32 and the wire end 33. The residual height of the wire bonding pad contact ball 31 after thinning is defined as H, the head diameter of the wire bonding pad contacting ball 31 after thinning as R, and the bottom diameter of the wire bonding pad contacting ball 31 after thinning as D, to match the thinning height reserved in Step B, wherein d is the diameter of the lead for lead bonding, which meets the following process parameter requirements: 2d≤R<3d and 10 μm≤H<30 μm; as shown by combining FIGS. 7 and 13c.

The example further comprises:

Step C1. Conducting metallization processing on the product surface whose wire bonding pad contact ball 31 is exposed after thinning, which can be done using methods such as chemical plating, sputtering, or vapor deposition to obtain metal layer 02, further manufacturing large bonding pad 311 that covers the wire bonding pad contact ball 31. The thickness of the large bonding pad 311 is 15 to 25 μm, and the edge of the large bonding pad 311 is more than 3 μm greater than the edge of the wire bonding pad contact ball 31, as shown in FIGS. 16a-16b.

Step D. Subjecting the packaging layer 4 for making the large bonding pad 311 to secondary plastic packaging or secondary compression encapsulation, with the thickness of the secondary packaging layer 5 being 35 to 50 μm, as shown in FIG. 16c.

Step E. Manufacturing chip blind holes 51 and circuit interconnecting holes 52 on the large bonding pad 311; subjecting the surface metal layer to patterned processing, thereby further enlarging the cross-sectional dimension of the wire bonding pad contact ball 31 exposed after thinning; defining the bottom size of the chip blind hole 51 as φ, the positioning accuracy of the hole processing equipment as ±Δ, and the pattern size of the large bonding pad 311 as T (ensuring full coverage); then subjecting the surface metal layer to patterned processing to achieve a patterned dimension parameter of T≥φ+2Δ, ensuring that the bottom of the chip blind hole 51 is above the large bonding pad 311 and that the large bonding pad 311 completely covers the wire bonding pad contact ball 31.

Step F. Subjecting the formed chip blind holes 51 and circuit interconnecting holes 52 to electroplating and patterned circuit processing to achieve electrical interconnection of the product, wherein internal connection line 9 connects the chip blind hole 51 and the circuit interconnecting hole 52.

In the example, the bottom size of the chip blind hole 51 is greater than the diameter D of the wire bonding pad contact ball 31.

### Example 6

In the example, in Step A, the lead frame 1 is equipped with a thickness adjustment protrusion 11, the thickness of which is 95% to 105% of the total thickness of the chip 2 and the wire bonding pad contact ball 31. To further reduce the processing difficulty of the large and small interconnecting holes, a 3D protrusion frame (thickness adjustment protrusion 11) that can reduce the size of the large interconnecting hole is designed. It significantly reduces the size of the large blind hole, greatly narrows the size difference between the interconnecting holes, and thereby greatly reduces the processing difference of the interconnecting holes.

The present invention further provides a semiconductor packaging structure made by the above semiconductor production method.

### Example 1

### A Semiconductor Packaging Structure

A semiconductor packaging structure includes a lead frame 1, a chip 2, and a packaging layer 4. The chip 2 is fixed on the lead frame 1, and the packaging layer 4 encases the chip 2 and the lead frame 1. The upper surface of the chip 2 is equipped with an AL bonding pad 21, and the AL bonding pad 21 is equipped with wire bonding pad contact balls 31 that have had the wire end 33 and transitional connecting platform 32 removed. The wire bonding pad contact balls 31 are electrically connected to surface bonding pads or surface circuits on the packaging layer 4 through chip blind holes 51;

A large bonding pad 311 is set above the wire bonding pad contact ball 31, with the size of the large bonding pad 311 greater than the bottom size of the chip blind hole 51; or there is no large bonding pad 311 set above the wire bonding pad contact ball 31, with the size of the wire bonding pad contact ball 31 greater than the bottom size of the chip blind hole 51.

### Example 2

In the example, there is more than one AL bonding pad 21, each of which is equipped with more than one wire end structure 3. The wire bonding pad contact ball 31 having more than one wire end structure 3 completely covers the surface of the AL bonding pad 21, and adjacent wire bonding pad contact balls 31 are eutecticly fused at the junction to form a large wire end structure 30.

The conducting wire used in the lead bonding process is a gold wire, copper wire or zinc-coated copper wire.

When the conducting wire used in the lead bonding process is a zinc-coated copper wire, the thickness of the zinc layer is 10% to 60% of the thickness of the conducting wire. Zinc has a low melting point and can form an intermediate that combines aluminum and copper, so it is an excellent transition layer metal.

The technical problem to be solved by the present invention is to develop a semiconductor packaging structure and a corresponding packaging method, for solving some problems present in traditional wire bonding packaging and new blind hole interconnection packaging rapidly, conveniently and at a low cost. It is cost-effective, has flexible design, and has a wide range of applications.

1. Low cost: significantly reducing the cost of the finished product by omitting additional processes of conventional chip aluminum bonding pad modification or RDL processing.

2. Low internal resistance: traditional wire bonding packaging has a small diameter, leading to a relatively large parasitic resistance parameter of the packaging body. By adopting a wire bonding and blind hole interconnected structure: the diameter of the contact ball on the contact surface of the joint between the wire end structure and the chip is much larger than the wire diameter, and the size of the blind hole and PCB or substrate circuit is also much larger than the wire diameter of conventional wire bonding, which effectively reduces the internal resistance of the packaging structure.

3. High thermal conductivity: traditional wire bonding packaging has a small diameter, leading to a small heat dissipation channel and insufficient cooling capacity. By adopting a wire bonding and blind hole interconnected structure: the diameter of the contact ball on the contact surface of the joint between the wire end structure and the chip is much larger than the wire diameter, and the size of the blind hole and PCB or substrate circuit is also much larger than the wire diameter of conventional wire bonding, which effectively increases the heat dissipation channel and enhances the thermal conductivity of the packaging structure.

4. Applicability: this solution offers flexible selections of process parameters for aluminum chips, with a wide range of applications.

The present invention is not limited to the above examples. The technical solutions of the above examples of the present invention can be combined with each other to form new technical solutions. Additionally, any technical solution formed by equivalent replacements falls within the protection scope of the present invention.

### INDUSTRIAL APPLICABILITY

A semiconductor packaging structure and a corresponding packaging method developed by the present invention is used for solving some problems present in traditional wire bonding packaging and new blind hole interconnection packaging rapidly, conveniently and at a low cost. It has the characteristics of low cost, low internal resistance and high thermal conductivity. As for aluminum chips, this solution offers flexible selections of process parameters, has a wide range of applications, can be applied industrially and can meet the requirements of industrial application.

1. A semiconductor packaging method, characterized in comprising:
Step A. mounting a chip on a lead frame, and producing a wire end structure on an AL bonding pad on the upper surface of the chip using a lead bonding process; the wire end structure including a wire bonding pad contact ball, a transition connection platform, and a wire end, which are tightly connected from bottom to top;
Step B. subjecting the lead frame whose wire end structure has been produced to first plastic packaging or compression encapsulation to realize full packaging of the chip and the wire end structure, with the top surface of the packaging layer being 20 to 50 μm higher than the top surface of the wire end structure;
Step C. thinning the packaging layer until the wire bonding pad contact ball is exposed, removing the transitional connecting platform and the wire end;
wherein a conducting wire used in the lead bonding process is a variable-diameter wire including more than N interconnected ball units, each of which includes a wire end part, a variable-diameter part, and a joint part, wherein the diameters of the wire end part and joint part are equal to the diameter of the conducting wire, and the variable-diameter part is larger in the middle and smaller at both ends, with the maximum diameter being 2 to 4 times the diameter of the conducting wire, and wherein Nis a natural number.

2. The semiconductor packaging method according to claim 1, characterized in that the conducting wire used in the lead bonding process is a gold or copper wire, wherein the diameter of the conducting wire is defined as d and the diameter of the wire bonding pad contact ball as D, with D≥3d.

3. The semiconductor packaging method according to claim 1, characterized in that the lead bonding process involves the use of more than two bonding needles, each of which guides conducting wires for simultaneous bonding, wherein more than two wire end structures are eutectically fused with each other to form a large wire end structure.

4. The semiconductor packaging method according to claim 1, characterized in that there is more than one AL bonding pad, each of which has more than one wire end structure, wherein the wire bonding pad contact ball having more than one wire end structure completely covers the surface of the AL bonding pad, and adjacent wire bonding pad contact balls are eutecticly fused at the junction.

5. The semiconductor packaging method according to claim 3, characterized in that the conducting wire used in the lead bonding process is a zinc-coated copper wire, with the thickness of the zinc layer being 10% to 60% of the thickness of the conducting wire.

6. The semiconductor packaging method according to claim 4, characterized in that the conducting wire used in the lead bonding process is a zinc-coated copper wire, with the thickness of the zinc layer being 10% to 60% of the thickness of the conducting wire.

7. The semiconductor packaging method according to claim 1, characterized in further comprising:
Step D. subjecting the thinned packaging layer to secondary plastic packaging or secondary compression encapsulation, with the thickness of secondary packaging layer being 35 to 50 μm;
Step E. manufacturing chip blind holes and circuit interconnecting holes on the wire bonding pad contact ball;
Step F. subjecting the formed chip blind holes and circuit interconnecting holes to electroplating and patterned circuit processing to achieve electrical interconnection of product.

8. The semiconductor packaging method according to claim 1, characterized in further comprising:
Step C1. conducting metallization processing on the product surface whose wire bonding pad contact ball is exposed after thinning, which can be done using methods such as chemical plating, sputtering, or vapor deposition to create a large bonding pad that covers the wire bonding pad contact ball, wherein the thickness of the large bonding pad is 15 to 25 μm, and the edge of the large bonding pad is more than 3 μm greater than the edge of the wire bonding pad contact ball;
Step D. subjecting the packaging layer for making the large bonding pad to secondary plastic packaging or secondary compression encapsulation, with the thickness of the secondary packaging layer being 35 to 50 μm;
Step E. manufacturing chip blind holes and circuit interconnecting holes on the large bonding pad;
Step F. subjecting the formed chip blind holes and circuit interconnecting holes to electroplating and patterned circuit processing to achieve electrical interconnection of the product.

9. The semiconductor packaging method according to claim 1, characterized in that in the Step A, the lead frame is equipped with a thickness adjustment protrusion.

10. The semiconductor packaging method according to claim 1, characterized in that the thickness of the thickness adjustment protrusion is 95% to 105% of the total thickness of the chip and the wire bonding pad contact ball.

11. The semiconductor packaging method according to claim 1, characterized in that in the Step A, the lead frame is equipped with a thickness adjustment protrusion, the thickness of which is 95% to 105% of the total thickness of the chip and the wire bonding pad contact ball.

12. A semiconductor packaging structure, characterized in comprising a lead frame, a chip, and a packaging layer, wherein the chip is fixed on the lead frame, and the packaging layer encases the chip and the lead frame, wherein the upper surface of the chip is equipped with an AL bonding pad equipped with wire bonding pad contact balls that have had the wire end and transitional connecting platform removed, and wherein the wire bonding pad contact balls are electrically connected to surface bonding pads or surface circuits on the packaging layer through chip blind holes.

13. The semiconductor packaging structure according to claim 12, characterized in that a large bonding pad is set above the wire bonding pad contact ball, with the size of the large bonding pad greater than the bottom size of the chip blind hole.

14. The semiconductor packaging structure according to claim 12, characterized in that there is no large bonding pad set above the wire bonding pad contact ball, with the size of the wire bonding pad contact ball greater than the bottom size of the chip blind hole.

15. The semiconductor packaging structure according to claim 12, characterized in that there is more than one AL bonding pad, each of which is equipped with more than one wire end structure, wherein the wire bonding pad contact ball having more than one wire end structure completely covers the surface of the AL bonding pad, and adjacent wire bonding pad contact balls are eutecticly fused at the junction to form a large wire end structure.
